(19) United States
(12) Patent Application Publication
(10) Pub. No.: US 2015/0097600 A1
(43) Pub. Date: Apr. 9, 2015

(54) PWM CONTROLLER WITH DRIVE SIGNAL ON CURRENT SENSING PIN

(71) Applicant: Texas Instruments Incorporated, Dallas, TX (US)

(72) Inventors: George Young, Blackrock (IE); Seamus M. O'Driscoll, Cloyne (IE); Andrew B. Keogh, Glanmire (IE)

(21) Appl. No.: 14/557,026

(22) Filed: Dec. 22, 2014

Related U.S. Application Data
(63) Continuation-in-part of application No. 13/944,588, filed on Jul. 17, 2013, now Pat. No. 8,922,255.

(30) Foreign Application Priority Data
Jul. 18, 2012 (GB) 1212741.1

(51) Int. Cl. H03K 3/012

(52) U.S. Cl. CPC H03K 3/012
USPC 327/109

(57) ABSTRACT

An integrated circuit (IC) having a pin having some dead-time when the pin is ineffective for use for a first purpose. The pin is used for a different purpose during that time wherein the pin is utilized to measure current when a main power transistor of a voltage converter is ON and used for driving an auxiliary or active-clamp when the main power transistor is OFF or used for generating a flag signal when the power transistor is OFF In addition, the integrated circuit (IC) could have a pin utilized for a first purpose to measure current during a first time when a power transistor of a voltage converter is ON and being utilized for a second purpose during the first time.

### CROSS-REFERENCE TO RELATED APPLICATIONS

This patent application is a continuation-in-part of U.S. patent application Ser. No. 13/944,588, which claims priority from Great Britain Provisional Patent Application No. 1212741.1, filed Jul. 18, 2012, which are incorporated herein by reference in their entirety for all purposes.

### FIELD OF THE INVENTION

The present invention relates to Integrated Circuit Devices and in particular to using a device pin for more than one purpose.

### BACKGROUND OF THE INVENTION

The ability to provide higher levels of functionality and features using a lower cost integrated circuit (IC) package with a lower pin-count is challenged by the need to provide a sufficient number of IC pins to accept all of the required input measurement signals from the system, and provide all the necessary control output signals required by the system. More features and functionality typically requires more system input signals to the IC and/or more output control signals to the system. More pins add more cost to the IC design (more die pads and associated electrostatic discharge (ESD), IC package and assembly cost, IC test cost. Since standard IC packages are available in a variety of sizes and pin-counts, it is not always possible to simply add one or a few extra pins to an existing package. In some cases, the need for more pins will push the design to the next higher pin-count package that is available, sometimes with the burden of extra cost if there are now more pins than are strictly necessary, resulting in some unused pins, exacerbating the cost increase.

### SUMMARY OF THE INVENTION

It is a general object to provide utilizing a pin of an integrated circuit (IC) for multiple purposes.

This and other objects and features can be found in accordance with an aspect of the disclosure to provide an integrated circuit (IC) comprising a pin having some dead-time when the pin is not effective for use for a first purpose. The pin is used for a different purpose during that time wherein the pin is utilized to measure current when a main power transistor of a voltage converter is ON and used for driving an auxiliary or active clamp transistor when the main power transistor is OFF.

Another aspect of the disclosure includes an integrated circuit (IC) comprising a pin having some dead time when the pin is ineffective for use for a first purpose. The pin is used for a different purpose during that time wherein the pin is utilized to measure current on a power transistor of a voltage converter is ON and used for generating a flag signal when the power transistor is OFF.

Another aspect of the disclosure includes an integrated circuit (IC) comprising a pin having some dead-time when the pin is ineffective for use for a first purpose. The pin is used for a different purpose during that time where the pin is utilized to measure current when a power transistor of a voltage converter is ON and used for transmitting information by modulating an output signal on the pin when the power transistor is OFF.

A further aspect of the disclosure includes an integrated circuit (IC) comprising a pin utilized for a first purpose to measure current during a first time when a power transistor of a voltage converter is ON and is utilized for a second purpose during the first time.

### BRIEF DESCRIPTION OF THE DRAWINGS

FIG. 1: Illustrative typical application circuit showing how Pin 3 of the PWM IC is used for dual purposes;

FIG. 2: Schematic of a CS pin interface;

FIGS. 3A-3E: Show example waveforms seen at various points in the circuit of FIG. 2;

FIG. 4: Schematic of a CS pin interface to both current sense signal and AUX drive switch;

FIG. 5: Example waveforms seen at various points in the circuit of FIG. 4;

FIG. 6: Schematic of a CS pin interface to both current sense signal and drive pulse peak detector;

FIG. 7: Example waveforms seen at various points in the circuit of FIG. 6;

FIG. 8: Schematic of a possible internal IC circuit & configuration to allow first dual purpose current sensing via the SW_IPC path into the internal current sense amplifier Al, while the driver block labelled DOMODE is in a high-impedance mode or floating mode;

FIG. 9: Schematic of a possible internal IC circuit & configuration to allow second dual purpose totem-pole or open drain pull-down driver operation by separately driving the upper/lower driver switches, while the current sense is isolated by opening SW_IPC and closing SW_IPZ;

FIG. 10: Illustrates a standard forward converter;

FIG. 11A: Illustrates an active-clamp forward converter utilizing a P-channel clamp transistor;

FIG. 11B: Illustrates an active-clamp forward converter utilizing an N-channel clamp transistor;

FIG. 12: Illustrates a standard flyback converter;

FIG. 13: Illustrates an active clamp flyback converter; and

FIG. 14A: Illustrates a circuit for communicating with other circuits;

FIGS. 14B-14G: Illustrate the waveforms of FIG. 14A;

FIG. 15A: Illustrates a semi-active-clamp flyback converter utilizing an N-type clamp circuit.

FIG. 15B: Illustrates a semi-active-clamp flyback converter utilizing a P-type clamp circuit; and

FIG. 16: Illustrates the waveforms of the circuit of FIGS. 15A or 15B.

### DESCRIPTION OF THE DRAWINGS

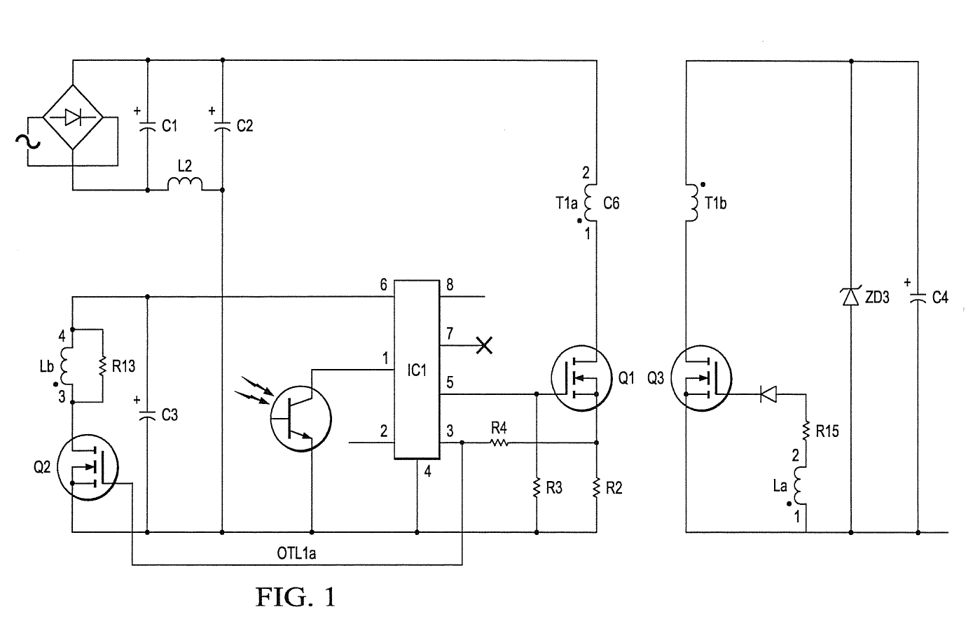

An example circuit is shown in FIG. 1. A drive signal on Pin 5 of IC1 drives a PWM signal to Q1 which in turn establishes a current in primary winding T1a. This is coupled to secondary T1b to charge capacitor C4 in accordance with known power conversion techniques.

The operation of the circuitry is that the Pin 3 operates to measure the current when the power FET Q1 (typically in a flyback) is ON. When the main FET is OFF, then this current sense pin can be used for other purposes, such as for driving a synchronous rectifier FET.

When the FET Q1 is driven, then the current develops a voltage across R2, typically limited to 500 mV and materially below the threshold of Q2. Under these conditions, Pin 3 has a high impedance, and thus the voltage across R2 is read at Pin 3 of IC1 with a minimal drop across R4.

When the FET Q1 is OFF, then Pin 3 becomes configured as an output of nominal range 0 to perhaps 3.5V. R4 limits the current through R2 when Pin 3 is high. Pin 3 going high allows Q2 to be driven, typically for a width corresponding (allowing for switching delays, margin etc.) to the desired operating time for synchronous rectifier Q3.

In the implementation as shown, a single pin, Pin 3, serves not only as a current sense pin for the PWM controller but also as an output to control the synchronous rectifier Q3 used in power conversion.

Further example possibilities will now be considered. On possibility is to generate an AUX drive signal that is complementary to the main DRV output, with programmed dead-times—this can be used to drive secondary side Synchronous Rectifier (SR), or an auxiliary primary-side clamp switch for active-clamp type topologies. The drive signal may be directly coupled to a circuit on the same ground or to a circuit on a floating or isolated ground.

Another possibility is to generate an AUX drive signal that is not complementary to the main DRV output, but is only active for a portion of the main DRV signal OFF-time. In this case, the AUX ON-time and the dead-times with the main DRV signal can be fixed, adjusted or adapted with operating conditions. This non-complementary AUX signal can be used to drive an auxiliary primary-side switch for optimized semi-active-clamp type topologies. The drive signal may be directly coupled to a circuit on the same ground, or magnetically, optically or otherwise coupled to a circuit on a floating or isolated ground.

An Aux Drive may be pulse width or pulse position modulated with DRV OFF time.

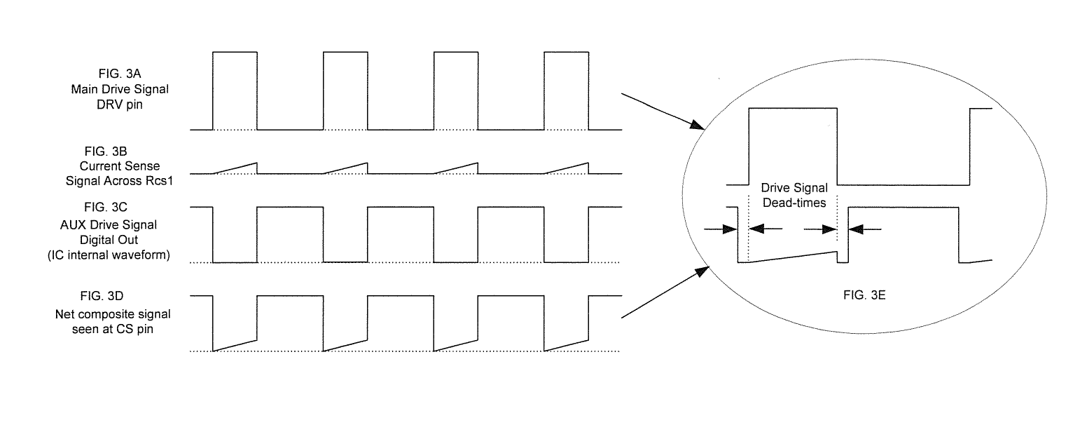

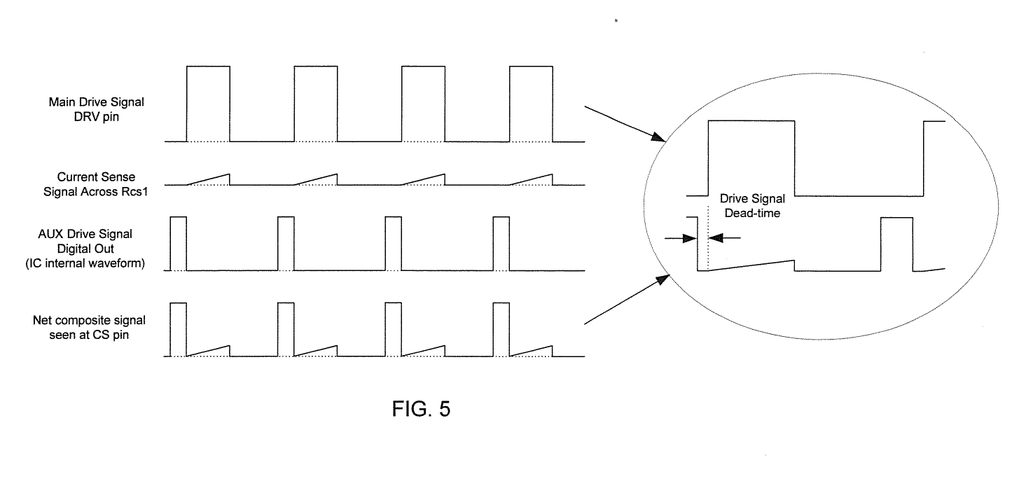

Taking either type of AUX drive signal as shown in FIG. 3 or 5, for example, and peak-detecting the “envelope” of the signal can provide a low frequency “flag” signal. This flag signal could be a digital signal, for example, which is used as an enable/inhibit signal for other circuits, or to flag fault or power good conditions, or a low-frequency signaling method for communication with another circuit. The communication signal may be directly coupled to a circuit on the same ground, or magnetically, optically or otherwise coupled to a circuit on a floating or isolated ground.

Taking either of these AUX drive signals and modulating the signal as a burst, can vary the frequency and/or duty cycle of the burst within the main OFF-period. This burst signal could be used as a low-frequency signaling method for communication with another circuit. Any number of signaling schemes could be employed e.g. AM (carrier duty cycle variation), FM (carrier frequency variation), FSK (carrier frequency shift keying), PSK (carrier phase shift keying), etc. The information can be encoded/decoded in various ways; the example below illustrates a very simple case. The communication could be used for a large number of purposes, such as: communication with a host, or with the load, etc. The communication signal may be directly coupled to a circuit on the same ground, or magnetically, optically, or otherwise, coupled to a circuit on a floating or isolated ground.

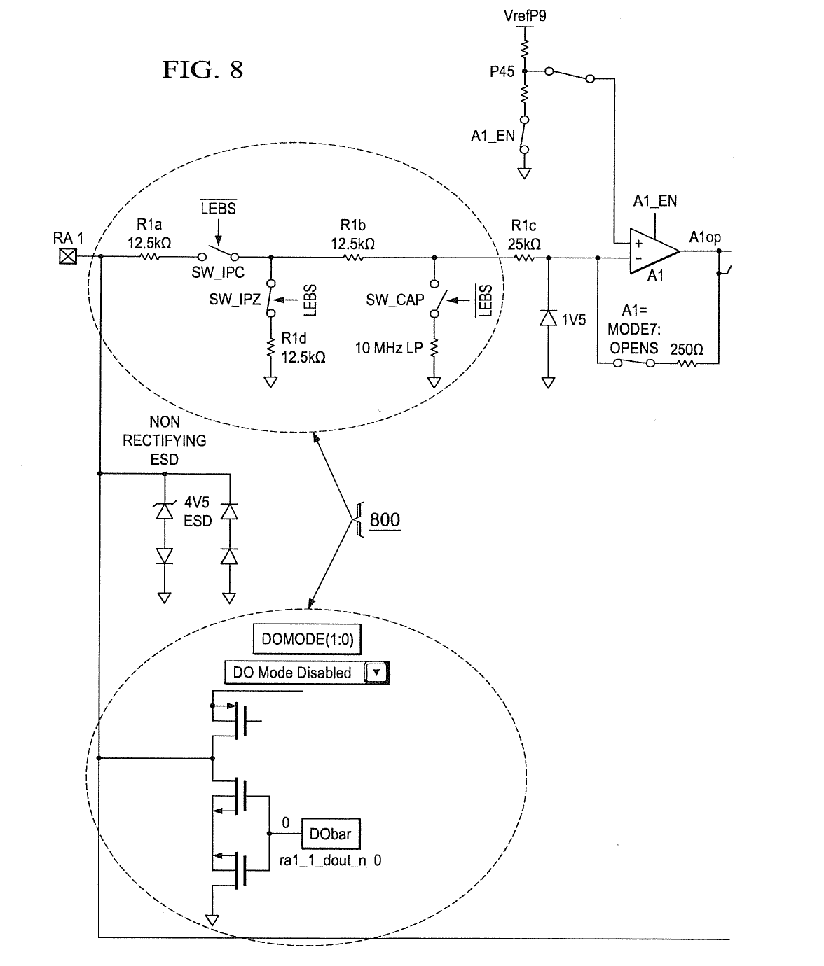

The internal circuitry of IC1 will now be considered. FIG. 8 shows, at 800, a standard IC1 configuration during “ON-Time” with the DO (Digital Output) mode disabled and SW_IPC closed (or under switched control) the CS pin pad configured as CS (Current-Sense) input (used to drive current control loop to generate PWM signals).

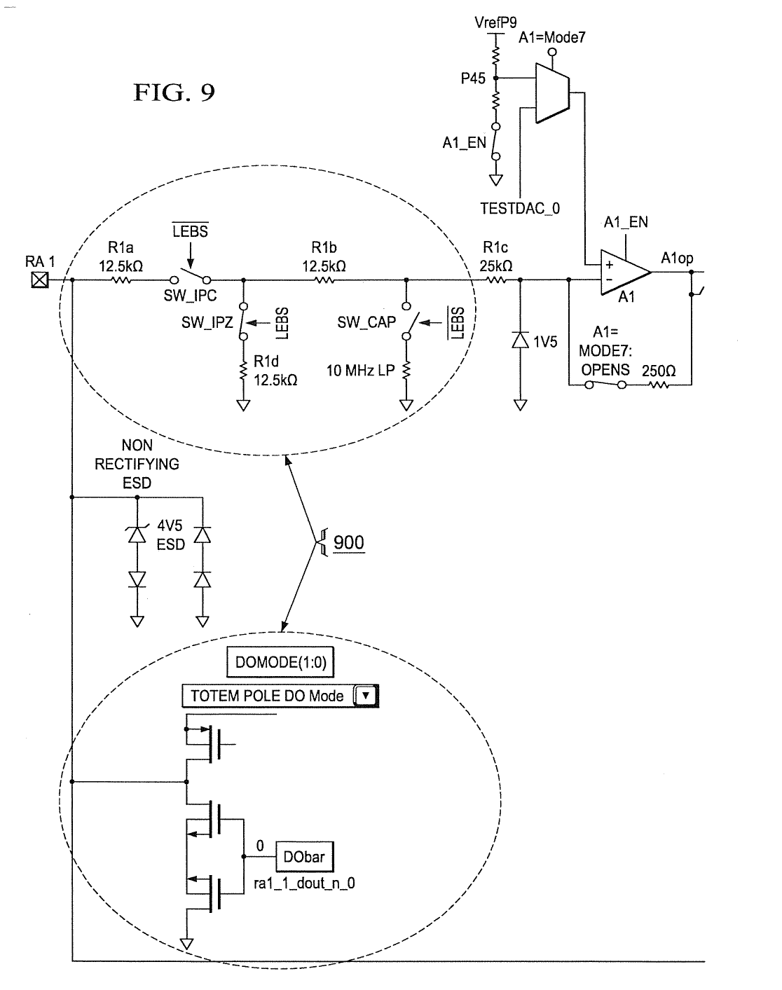

FIG. 9 shows, at 900, an alternate IC1 configuration during “OFF-Time with the DO Mode set to “totem-pole” output, can drive digital TTL output signals to pad (CS pin), SW_IPC is opened to isolate the internal analogue circuitry, and SW_PZ is closed (to ensure that the current loop operates exactly as it otherwise would, i.e., sees the same input impedance with zero input signal).

Referring now to the semi-active-clamp circuit referred to in paragraph [0034], the applicability of an aspect to forward converters will be described in connection with FIG. 10. In FIG. 10, a source of voltage Vin is applied to a transformer T, the other terminal of which is connected to ground through a primary switch transistor Q1. A capacitor Cin is coupled between Vin and ground. A resistor R1 and the capacitor C1 is connected between Vin and the cathode of a diode D1, the anode of which is connected to the node between a transformer T and the transistor Q1. The secondary of transformer T comprises diodes D3 and D4 and inductor L1, generating a voltage Vout across an output capacitor Co.

In this circuit, the ON-time of the main primary switch transistor Q1 is varied in order to regulate the output voltage Vout against changes in the input voltage Vin and load current lout. When transistor Q1 is turned ON, the transformer is energized, with the build-up of the current and associated magnetic flux in the core. During the OFF-time, the flux in the transformer must be reset, which is achieved by the voltage across capacitor C1 in a snubber circuit D1, R1, C1. The higher the voltage across capacitor C1, the shorter the reset interval. However, the peak voltage across capacitor C1 in a steady-state operation will depend upon the values of resistor R1 and capacitor C1, the transformer magnetizing and leakage inductances and the load current. As such, the reset interval is not controlled, since the voltage across capacitor C1 varies with load conditions. Thus, the voltage rating of transistor Q1 will be a function of the maximum Vin plus the peak voltage across capacitor C1, which yields a voltage rating which must be higher and results in the fact that the ON-resistance of transistor Q1 cannot be optimized.

FIG. 11A shows an active-clamp for a converter utilizing a P-channel active clamp transistor. FIG. 11B shows a semi-active-clamp forward converter utilizing an N-channel active clamp transistor. An active-clamp forward converter has a main primary switch Q1, as shown in FIGS. 11A-11B, plus an auxiliary switch Q2 which may be a P-FET (FIG. 11A) or N-FET (FIG. 11B). In this type of circuit, the transistor Q2 is driven with the complement of the Q1 gate drive signal so that the clamp capacitor (in series with transistor Q2) forces the active reset of the transformer T during the OFF-time of the transistor Q1. This forces the reset interval to extend to the full duration of the OFF-time, lowering the amplitude of the reset voltage across the clamp capacitor and lowering the voltage stress on the main primary switch transistor Q1. This allows a lower voltage rated device to be used for transistor Q1, allowing efficiency to be better optimized and improved. Appropriate dead-time must be provided between the turn-OFF occurrence of transistor Q1 and the turn-ON occurrence of transistor Q2, and then again between the turn-OFF of transistor Q2 and the turn-ON of transistor Q1 to avoid cross conduction (crowbar current), where both switches are turned ON simultaneously. This dead-time can be tuned to allow zero-voltage or near zero-voltage switching of transistors Q1 and Q2, reducing switching losses and further improving efficiency compared to standard forward converter topology.

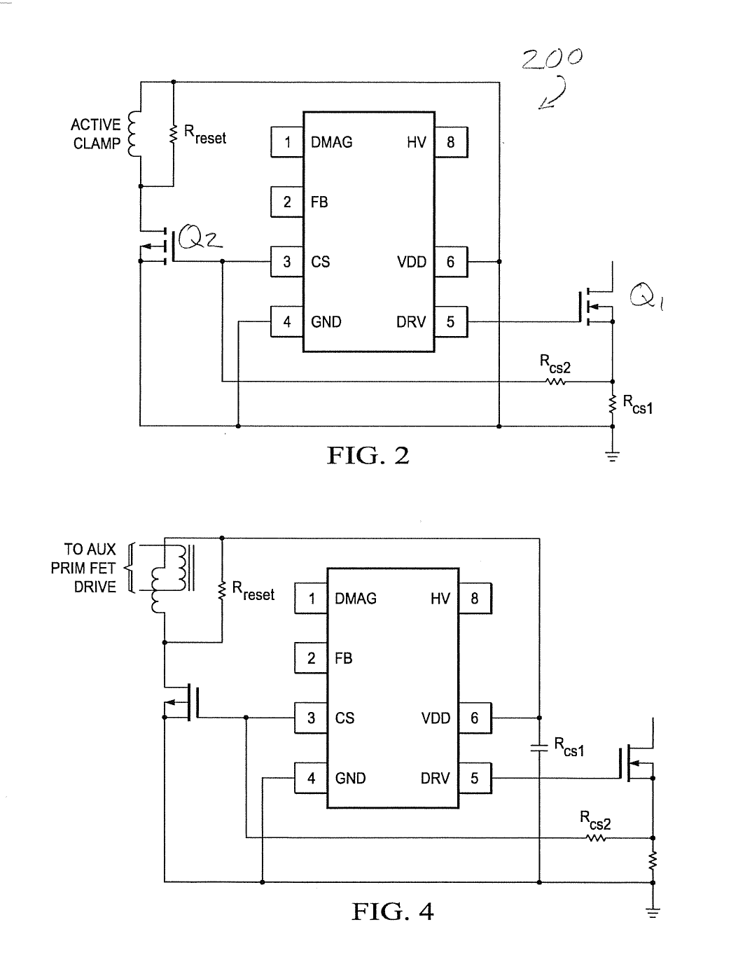

Referring now to FIG. 2, circuitry utilizing an aspect of the disclosure for generating the active-clamp signal for transistor Q2 is shown, generally as 200. The current through the main primary switch transistor Q1 is measured by resistor R_{CS1} which is between the transistor Q1 and ground. This signal is coupled via R_{CS2} to the input Pin CS (current sense) Pin 3. The current sense voltage across resistor R_{CS1} is of a low value, typically hundreds of millivolts, in order to keep the power losses caused by the shunt resistor at a minimum. This generates the voltage shown in FIG. 3B during the ON-time for the transistor Q1 which is driven by the signal shown in FIG. 3A. During the OFF-time for the main transistor Q1, the integrated circuit can develop the AUX drive signal to drive the active clamp transistor Q2. This results in a composite waveform signal shown in FIG. 3D as a composite signal at the CS pin. Most of the voltage utilized to drive the active clamp transistor Q2 is developed across resistor R_{CS2} because of the low value of the shunt resistor R_{CS1}, for example 100 milliohms, and the much higher value of resistor R_{CS2}, for example 10 kilo ohms. Thus, the active-clamp voltage at Pin 3 can be generated without the need for additional pins for the IC.

FIGS. 8 and 9 show the internal circuitry of the IC for pin 3, shown as RA1 in the figures. As discussed above, in connection with paragraphs [0038-0039], the current measuring circuitry at the top of the figures include a current measuring circuit which can be switched in or out of being connected to the pin, and a tri-stateable totem-pole output circuit at the bottom of the figures. This totem-pole circuit is utilized to provide the secondary feature drive signals on this current sense pin.

Switches SW_IPC and SW_IPZ are used to connect the internal current sense blocks to the CS pin, as required. These switches are typically driven with complementary signals, so that the current sense circuitry is alternately connected to either the CS pin or to GND, during each pulse width modulation (PWM) cycle. The switches can be controlled by hardware signals derived from a timer/oscillator that is synchronized to the PWM generation, or as part of the PWM generation in the first place. The switches may also be controlled by firmware. These switches allow the internal current sense circuitry to be disconnected from the CS pin during time intervals when the CS pin is being internally driven.

The bottom circled block includes the Digital Output (DO) driver, which allows the CS pin to be driven as a push-pull output or an open-drain pull-down. This driver is connected to an internal 4.5 V rail inside the IC, so the external drive signal at the CS pin will be approx. 4.0 to 4.5 V, depending on loading. The DO signal is controlled by firmware, but in an alternative implementation, it could be controlled by hardware signals, ideally the same synchronized timer/oscillator that controls switches SW_IPC and SW_IPZ.

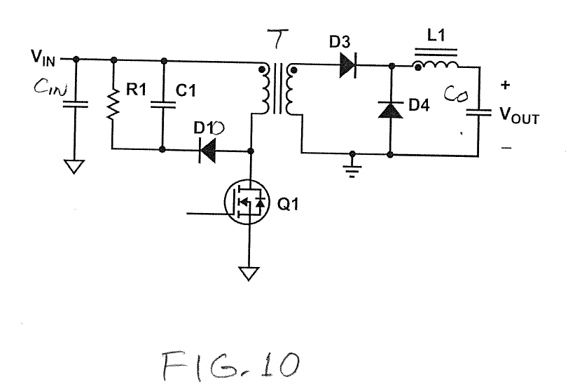

The active-clamp technique can also be applied to a flyback converter to achieve similar efficiency benefits. FIG. 12 shows a standard flyback converter example. FIG. 13 shows an active-clamp flyback converter example. In FIG. 13, the required complementary drive signal for the auxiliary clamp transistor Q2 can be generated by utilizing the techniques discussed above and by timesharing the CS pin during the OFF-time of the main primary switch transistor Q1. The signal required to drive transistor Q2 would have the appropriate dead-times to avoid cross-conduction, as discussed above. Thus, the same technique for dual use of the CS pin can be used for active-clamp flyback converters, thus saving one pin on the integrated circuit.

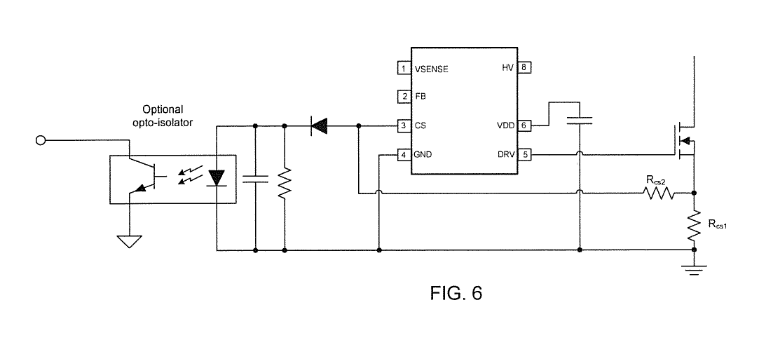

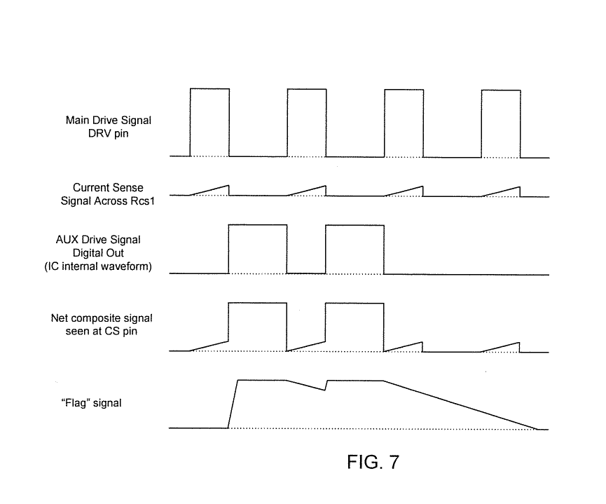

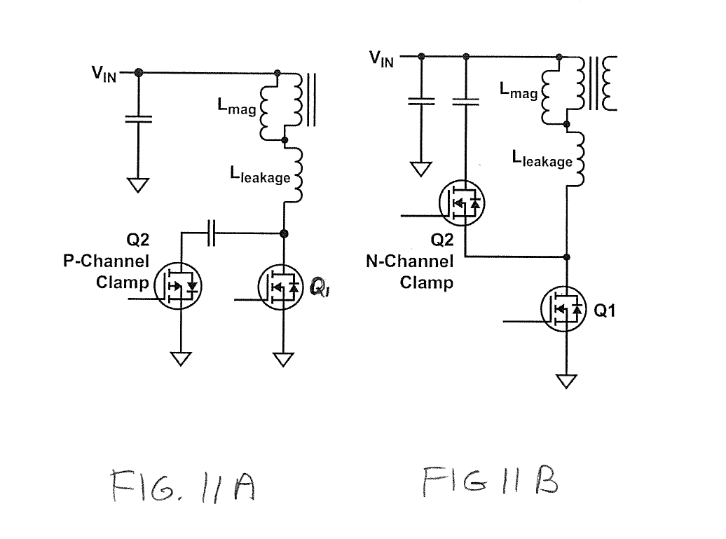

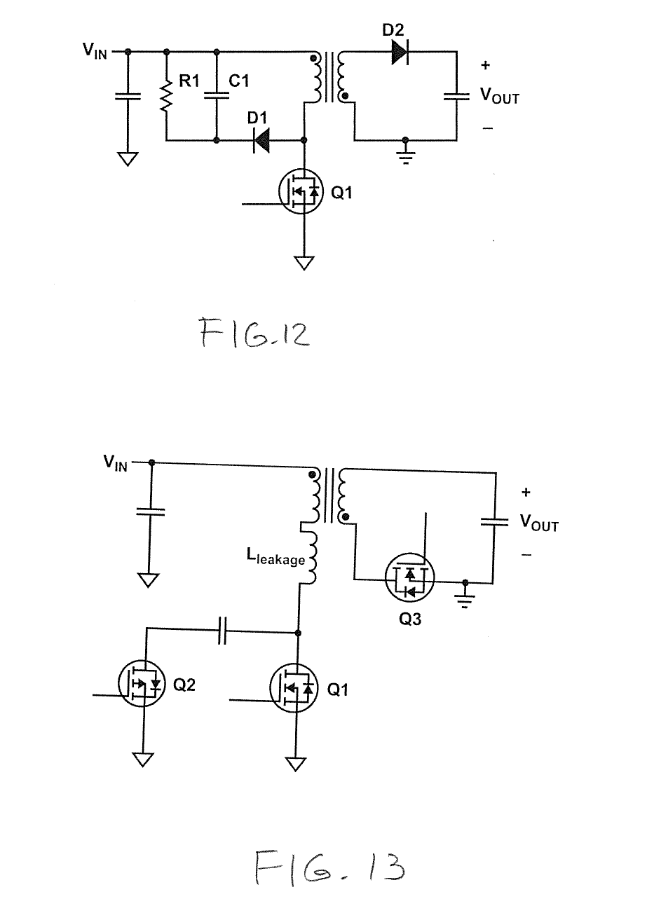

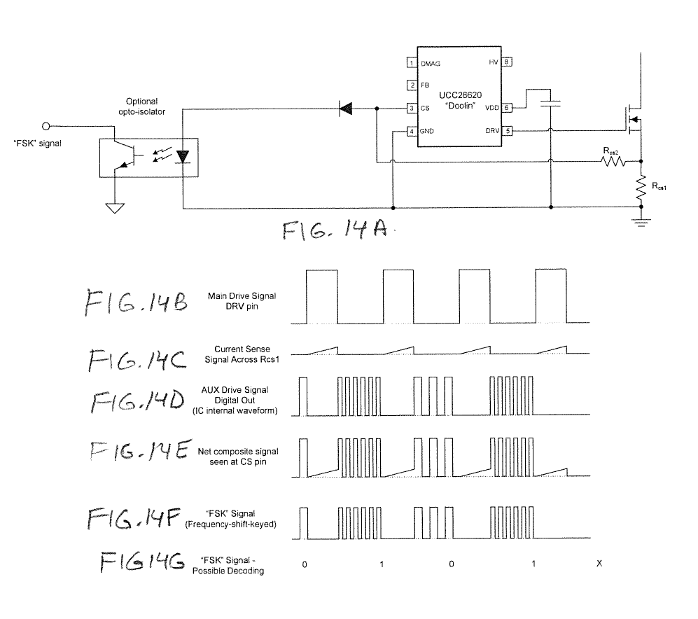

Referring now to paragraph [0037] and to FIG. 14, an example is shown in which the CS pin is utilized to communicate with other circuits using frequency shift-keying (FSK) signals. The circuit is very similar to the circuit shown in FIG. 6, except that the resistor and capacitor across the input to the opto-isolator is missing because this is not the peak detecting circuit in this application. The main drive signal on the DRV pin, driving the main primary switch transistor Q1, is shown in FIG. 14B. The current sense signal across resistor R_{CS1} is shown in FIG. 14C. The AUX drive signal is shown in FIG. 14D and a composite signal is shown in FIG. 14E. The resulting FSK signal is shown in FIG. 14F and possible decoding of that signal is shown FIG. 14G. Similarly, amplitude modulation, frequency modulation, phase modulation, and duty cycle modulation can be utilized in this example.

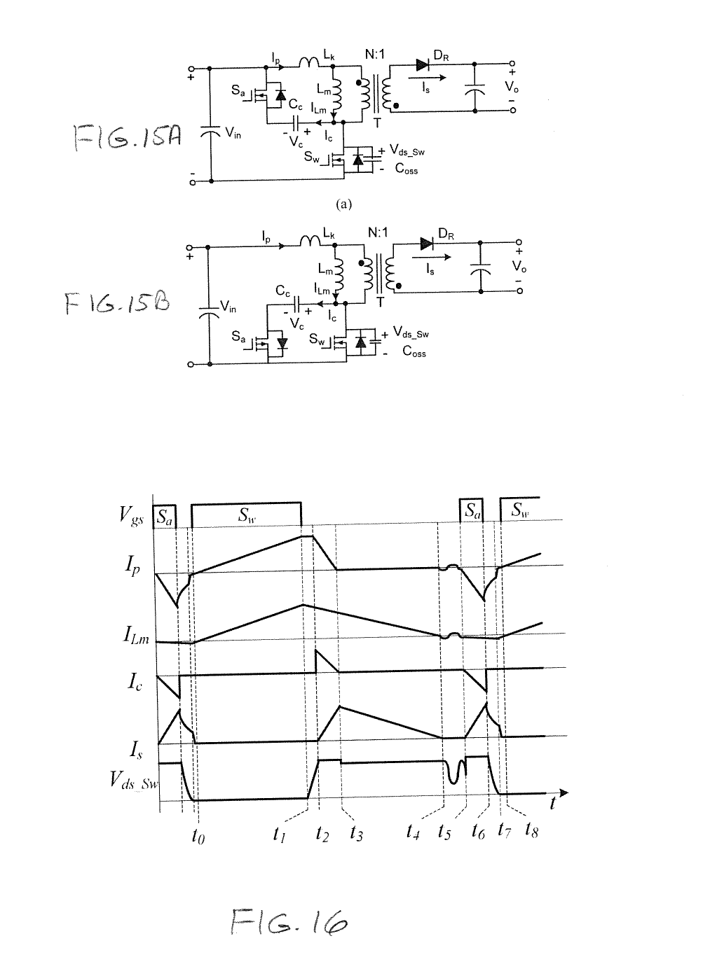

Referring to paragraph [0034], FIGS. 15A and 15B show a semi-active-clamp circuit. FIG. 15A shows an N-type clamp circuit and FIG. 15B shows a P-type clamp circuit.

The circuit schematics are similar to the conventional active-clamp flyback. Two possible versions are shown, with P-Ch FET (easier to drive from low-side control circuit) and high-side N-Ch FET (requires level shifting high-side gate drive, using a pulse transformer or a high-side high-voltage gate driver).

The main difference with the semi-active clamp is that the AUX switch is not driven with the complement of the main switch. Instead, as shown in FIG. 16, the AUX switch is only turned ON for a short time, near the end of the OFF-time interval of the main switch. It is only turned ON long enough to build up current in the opposite direction in the transformer magnetizing and leakage inductances. During the dead-time between turn-OFF of the AUX switch, and subsequent turn-ON of the main switch for the next PWM cycles, the negative current built up in the transformer inductances will discharge the capacitance Coss at the main switch node, leading to zero-voltage switching of the main switch and improved efficiency. There is a further improvement in efficiency in a similar fashion to conventional active-clamp flyback, since the energy in the leakage inductance is transferred to the clamp capacitor, and from there, it will be transferred back to the output when the AUX switch is turned-ON.

The main advantage of the semi-active-clamp flyback topology over the conventional active-clamp flyback, is that the circulating current in the clamp and AUX switch is much less, only enough to achieve the desired zero-voltage switching of the main switch. This improves the efficiency under light-load conditions, where the circulating power of the conventional active-clamp is quite significant. It also lends itself to a variable frequency operation, where the switching frequency can be decreased at light-load conditions to further improve efficiency.

Typical waveforms are shown in FIG. 16 with labelling consistent with the labelling of FIGS. 15A-15B.

As can be seen, the AUX switch gate drive Sa is a short pulse, followed by short dead-time, ahead of the turn-ON of the gate drive for the main switch Sw in the next PWM cycle. Generation of these drive pulses lend themselves readily available to the dual-use method of using the CS pin as an AUX drive output during the OFF-time, during the time that the CS input function is not required.

Although the disclosure has been described in detail, it should be understood that various changes, substitutions and alterations can be made thereto without departing from the spirit and scope of the invention as defined by the appended claims.

1. An integrated circuit (IC) comprising a pin having some dead-time when the pin is ineffective for use for a first purpose, the pin being used for a different purpose during that time wherein the pin is utilized to measure current when a main power transistor of a voltage converter is ON and used for driving an auxiliary or active-clamp when the main power transistor is OFF.

2. The IC of claim 1 wherein a current measuring circuit is switchably connected to the pin.

3. The IC of claim 2 wherein the driver for the active-clamp has a totem-pole output.

4. The IC of claim 1 wherein the IC is used to control a forward converter.

5. The IC of claim 1 wherein the IC is used to control a flyback converter.

6. An integrated circuit (IC) comprising a pin having some dead-time when the pin is ineffective for use for a first purpose, the pin being used for a different purpose during that time wherein the pin is utilized to measure current on a power transistor of a voltage converter is ON and used for generating a flag signal when the power transistor is OFF.

7. The IC of claim 4 wherein the flag signal is a digital indication of a parameter.

8. The IC of claim 5 wherein the IC is used to control a forward converter.

9. The IC of claim 5 wherein the IC is used to control a flyback converter.

10. The IC of claim 6 wherein a current measuring circuit is switchably connected to the pin.

11. The IC of claim 10 wherein an output driver has a totem-pole output.

12. An integrated circuit (IC) comprising a pin having some dead-time when the pin is ineffective for use for a first purpose, the pin being used for a different purpose during that time where the pin is utilized to measure current when a power transistor of a voltage converter is ON and used for transmitting information by modulating an output signal on the pin when the power transistor is OFF.

13. The IC of claim 8 wherein the modulation is a frequency modulation.

14. The IC of claim 8 wherein the modulation is an amplitude modulation.

15. The IC of claim 8 wherein the modulation is a phase modulation.

16. The IC of claim 8 wherein the modulation varies the duty cycle of the signal.

17. The IC of claim 8 wherein current measuring circuitry is switchably connected to the pin.

18. The IC of claim 17 wherein an output driver has a totem-pole output.

19. An integrated circuit (IC) comprising a pin utilized for a first purpose to measure current during a first time when a power transistor of a voltage converter is ON and being utilized for a second purpose during the first time.

20. The IC of claim 19 wherein the second purpose is to drive an auxiliary primary-side switch of a semi-active-clamp circuit.
